(19) United States
(12) Patent Application Publication
(10) Pub. No.: US 2025/0113465 A1
(43) Pub. Date: Apr. 3, 2025

(54) THERMAL MANAGEMENT CIRCUIT

(71) Applicant: TOYOTA JIDOSHA KABUSHIKI KAISHA, Toyota-shi (JP)

(72) Inventors: Hidefumi AIKAWA, Okazaki-shi (JP); Makoto IKEGAMI, Obu-shi (JP)

(73) Assignee: TOYOTA JIDOSHA KABUSHIKI KAISHA, Toyota-shi (JP)

(21) Appl. No.: 18/731,696

(22) Filed: Jun. 3, 2024

(30) Foreign Application Priority Data
Oct. 2, 2023 (JP) 2023-171281

(51) Int. Cl. H05K 7/20; F25B 1/00; F25B 41/26

(52) U.S. Cl. CPC H05K 7/20381; F25B 1/00; F25B 41/26; H05K 7/20318; H05K 7/20327

(57) ABSTRACT

The thermal management circuit includes a battery circuit (low-temperature circuit) (apparatus arrangement circuit) through which a heat medium that is heat-exchanged with a battery (eAxel) (temperature adjustment target apparatus) circulates, a refrigeration cycle connected to the chiller and the water-cooled capacitor, a heat exchange device that performs heat exchange between the outside air and the heat medium, and a switching device. The heat exchanger device includes a LT radiator (first heat exchanger), a HT radiator (second heat exchanger), and a supercooling capacitor (third heat exchanger), which are provided separately from each other. The connection state between each of LT radiator, HT radiator, and the supercooling capacitor and each of the of the battery circuit (low-temperature circuit) and the refrigeration cycle is switched by a switching device.

### CROSS-REFERENCE TO RELATED APPLICATION

This application claims priority to Japanese Patent Application No. 2023-171281 filed on Oct. 2, 2023, incorporated herein by reference in its entirety.

### BACKGROUND

### 1. Technical Field

The present disclosure relates to a thermal management circuit.

### 2. Description of Related Art

Japanese Unexamined Patent Application Publication No. 2020-185880 (JP 2020-185880 A) discloses a coolant circuit that is provided with a first heat exchanger and a second heat exchanger for heat exchange between outside air and coolant. The coolant circuit is configured such that a circuit state in which the first heat exchanger and the second heat exchanger are connected in series and a circuit state in which the first heat exchanger and the second heat exchanger are connected in parallel can be switched. The heat exchange efficiency of the heat medium (coolant) is adjusted by switching the connection state between the first heat exchanger and the second heat exchanger.

### SUMMARY

In the coolant circuit of JP 2020-185880 A, as described above, the heat exchange efficiency of the heat medium is adjusted by switching the connection state of the first heat exchanger and the second heat exchanger. On the other hand, it is desired to make the heat exchange efficiency of the heat medium more easily adjustable.

The present disclosure has been made to solve the above issue, and an object of the present disclosure is to provide a thermal management circuit in which the heat exchange efficiency of a heat medium can be easily adjusted.

A thermal management circuit according to an aspect of the present disclosure is
a thermal management circuit installed in an electrical apparatus. The thermal management circuit includes:
an apparatus arrangement circuit through which a heat medium that exchanges heat with a temperature adjustment target apparatus is circulated, the temperature adjustment target apparatus being an apparatus that is a target of temperature adjustment;
a refrigeration cycle that is connected to a chiller and a water-cooled capacitor;
a heat exchange device that performs heat exchange between outside air and the heat medium; and
a switching device that is able to switch a circulation route of the heat medium.

The heat exchange device includes a first heat exchanger, a second heat exchanger, and a third heat exchanger that are provided separately from each other.

A connection state between each of the first heat exchanger, the second heat exchanger, and the third heat exchanger and each of the apparatus arrangement circuit and the refrigeration cycle is switched by the switching device.

In the thermal management circuit according to the aspect of the present disclosure, as described above, the connection state between each of the first heat exchanger, the second heat exchanger, and the third heat exchanger and each of the apparatus arrangement circuit and the refrigeration cycle is switched by the switching device. Accordingly, since three heat exchangers are provided in the heat exchange device, the combination of the heat exchangers used for the heat exchange can be diversified as compared with a case where two heat exchangers are provided. As a result, the adjustment of the heat exchange efficiency by the heat exchange device can be facilitated. Accordingly, the temperature adjustment of the temperature adjustment target apparatus in the apparatus arrangement circuit can be facilitated and air conditioning requirements can be easily responded to through the refrigeration cycle.

In the thermal management circuit according to the aspect,
the third heat exchanger may be connected to the refrigeration cycle.

The water-cooled capacitor may include a condensing unit that changes the heat medium from a vapor phase to a liquid phase.

In the third heat exchanger, the heat medium changed to the liquid phase in the condensing unit and the outside air may exchange heat.

With the configuration, the third heat exchanger enables the outside air and the refrigerant in the refrigeration cycle to easily exchange heat.

In the thermal management circuit according to the aspect,
the water-cooled capacitor may include a condensing unit that changes the heat medium from a vapor phase to a liquid phase, and a supercooling unit that cools the heat medium changed to the liquid phase in the condensing unit.

The condensing unit and the supercooling unit may be connected to the switching device through a first flow path and a second flow path, respectively.

Each of the first flow path and the second flow path may include a first direction flow path through which the heat medium circulates toward the switching device, and a second direction flow path through which the heat medium circulates in a direction opposite to a direction in which the heat medium circulates in the first direction flow path.
With the configuration, in each of the closed circuit passing through the condensing unit and the first flow path and the closed circuit passing through the supercooling unit and the second flow path, heat exchange of the heat medium can be performed independently of each other. As a result, the heat exchange efficiency of the heat medium can be more easily adjusted.

In the thermal management circuit according to the aspect,
the water-cooled capacitor may include a condensing unit that changes the heat medium from a vapor phase to a liquid phase, and a supercooling unit that cools the heat medium changed to the liquid phase in the condensing unit.

The condensing unit and the supercooling unit may be connected to the switching device through a third flow path and a fourth flow path, respectively.

The third flow path may be constituted by a third direction flow path through which the heat medium circulates from the condensing unit toward the switching device.

The fourth flow path may be constituted by a fourth direction flow path through which the heat medium circulates from the switching device toward the supercooling unit.

With the configuration, the configuration of the thermal management circuit can be simplified as compared with a case where each of the third flow path and the fourth flow path is constituted by a plurality of flow paths.

In the thermal management circuit according to the aspect,
each of the first heat exchanger and the third heat exchanger may be disposed on an upstream side of the second heat exchanger in a circulation direction of the outside air flowing into the heat exchange device.

With the configuration, since the outside air passes through the first heat exchanger and the third heat exchanger before passing through the second heat exchanger, the temperature of the outside air passing through the first heat exchanger and the third heat exchanger can be made relatively low. As a result, the amount of heat dissipation of the heat medium in the first heat exchanger and the third heat exchanger can be increased.

According to the present disclosure, it is possible to easily adjust the heat exchange efficiency of the heat medium by using the first to third heat exchangers.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a configuration of a thermal management system according to a first embodiment;

FIG. 2 is a diagram illustrating a circuit pattern 1A of the thermal management circuit according to the first embodiment;

FIG. 3 is a diagram illustrating a circuit pattern 1B of the thermal management circuit according to the first embodiment;

FIG. 4 is a diagram illustrating a circuit pattern 1C of the thermal management circuit according to the first embodiment;

FIG. 5 is a diagram illustrating a circuit pattern 1D of the thermal management circuit according to the first embodiment;

FIG. 6 is a diagram illustrating a circuit pattern 1E of the thermal management circuit according to the first embodiment;

FIG. 7 is a diagram illustrating correspondence between various temperature conditions and circuit patterns in the thermal management circuit according to the first embodiment;

FIG. 8 is a diagram illustrating a configuration of a thermal management system according to a second embodiment;

FIG. 9 is a diagram illustrating a circuit pattern 2A of the thermal management circuit according to the second embodiment;

FIG. 10 is a diagram illustrating a circuit pattern 2B of the thermal management circuit according to the second embodiment;

FIG. 11 is a diagram illustrating a circuit pattern 2C of the thermal management circuit according to the second embodiment;

FIG. 12 is a diagram illustrating a circuit pattern 2D of the thermal management circuit according to the second embodiment;

FIG. 13 is a diagram illustrating a circuit pattern 2E of the thermal management circuit according to the second embodiment;

FIG. 14 is a diagram illustrating correspondence between various temperature conditions and circuit patterns in the thermal management circuit according to the second embodiment;

FIG. 15 is a diagram illustrating a configuration of a thermal management system according to a third embodiment;

FIG. 16 is a diagram illustrating a circuit pattern 3A of the thermal management circuit according to the third embodiment;

FIG. 17 is a diagram illustrating a circuit pattern 3B of the thermal management circuit according to the third embodiment;

FIG. 18 is a diagram illustrating a circuit pattern 3C of the thermal management circuit according to the third embodiment;

FIG. 19 is a diagram illustrating a circuit pattern 3D of the thermal management circuit according to the third embodiment;

FIG. 20 is a diagram illustrating a circuit pattern 3E of the thermal management circuit according to the third embodiment; and

FIG. 21 is a diagram illustrating correspondence between various temperature conditions and circuit patterns in the thermal management circuit according to the third embodiment.

### DETAILED DESCRIPTION OF EMBODIMENTS

Hereinafter, embodiments of the present disclosure will be described in detail with reference to the drawings. It should be noted that the same or corresponding portions in the drawings are designated by the same reference signs and repetitive description will be omitted.

### First Embodiment

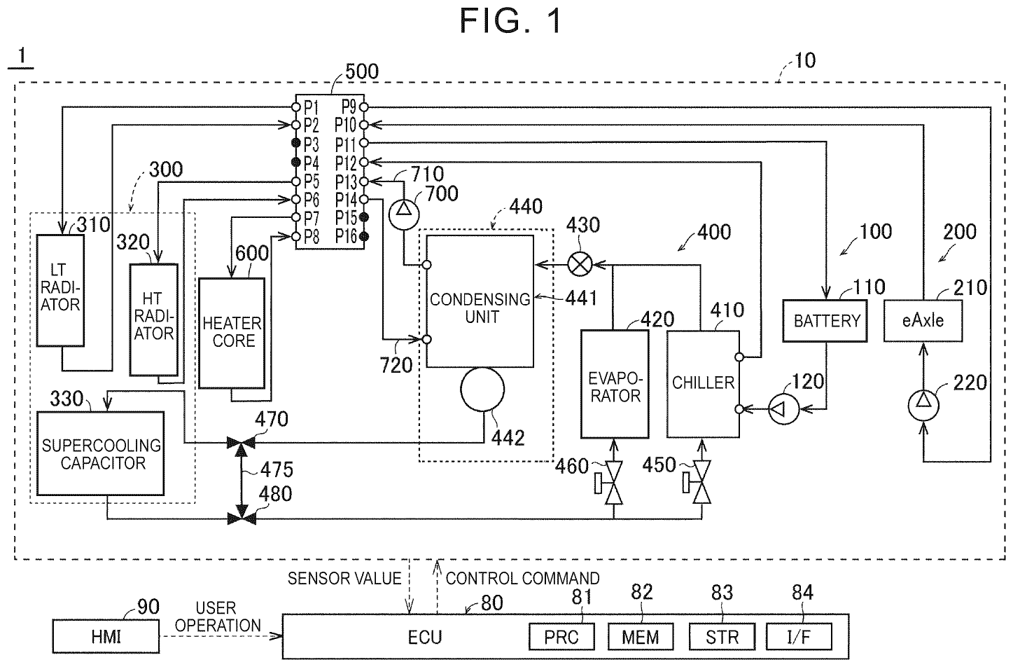

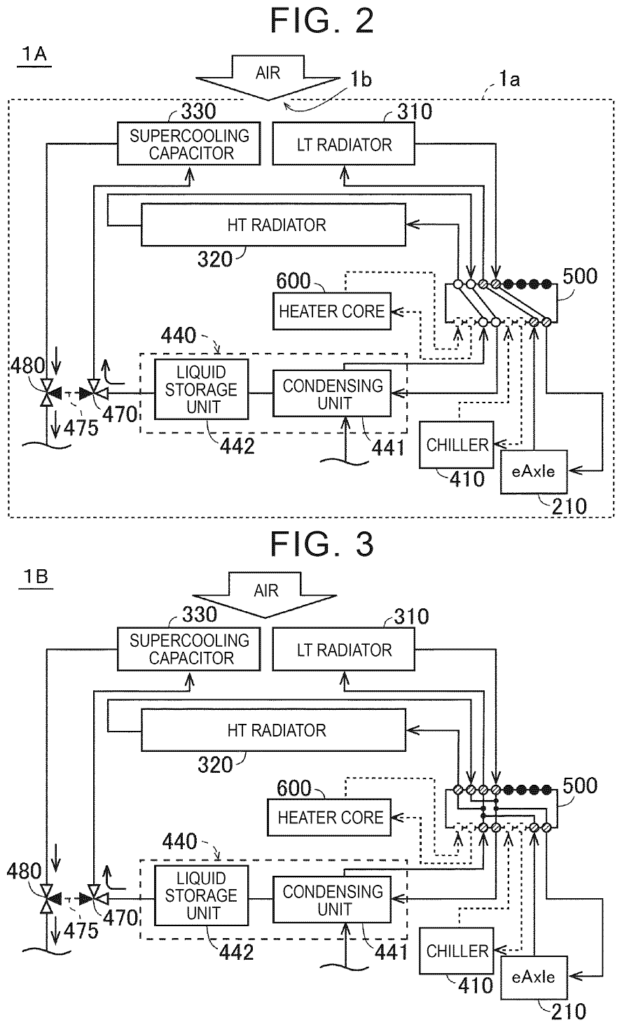

FIG. 1 is a diagram illustrating an overall configuration of a thermal management system 1 including a thermal management circuit 10 according to a first embodiment. The thermal management system 1 includes a thermal management circuit 10 and an electronic control unit (ECU) 80 and Human Machine Interface (HMI) 90. The thermal management system 1 is mounted on, for example, an electrified vehicle 1a (see FIG. 2). Note that electrified vehicle 1a is an exemplary “electrical apparatus” of the present disclosure.

The thermal management circuit 10 includes a battery circuit 100, a low-temperature circuit 200, a heat exchange device 300, a refrigeration cycle 400, a switching device 500, a heater core 600, and a water pump 700. In this specification, the heat medium flowing in the refrigeration cycle 400 is referred to as a “refrigerant”, and the heat medium flowing in another circuit is referred to as a “cooling liquid”. Note that each of the refrigerant and the cooling liquid is an example of the “heat medium” of the present disclosure.

The battery circuit 100 connects the later-described chiller 410 and the switching device 500. The battery circuit 100 includes a battery 110 and a water pump 120. The battery 110 is an apparatus to be subjected to temperature adjustment (for example, cooling). In the battery circuit 100, a cooling liquid that exchanges heat with the battery 110 flows. The battery 110 stores electric power used for traveling of electrified vehicle 1a or the like. The water pump 120 is disposed on the downstream side of the battery 110 and on the upstream side of the chiller 410 in the flow direction of the cooling liquid flowing through the battery circuit 100. The battery 110 and the battery circuit 100 are examples of the “temperature adjustment target apparatus” and the “apparatus arrangement circuit” of the present disclosure, respectively.

The low-temperature circuit 200 comprises an eAxle 210 and a water pump 220. In the low-temperature circuit 200, a coolant that is heat-exchanged with eAxle 210 flows. eAxle 210 includes a Power Control Unit (PCU) (not shown), an oil cooler, and the like. eAxle 210 is an apparatus to be temperature-controlled (for example, cooled). The water pump 220 is disposed upstream of eAxle 210 in the flow direction of the coolant flowing through the low-temperature circuit 200. Note that eAxle 210 and the low-temperature circuit 200 are exemplary “temperature adjustment target apparatus” and “apparatus arrangement circuit” of the present disclosure, respectively.

The heat exchange device 300 includes a Low Temperature (LT) radiator 310, a High Temperature (HT) radiator 320, and a supercooling capacitor 330. LT radiator 310, HT radiator 320, and the supercooling capacitor 330 are provided separately (independently) from each other. In each of LT radiator 310 and HT radiator 320, the outside air and the coolant are heat-exchanged. The supercooling capacitor 330 exchanges heat between the outside air and the refrigerant in the refrigeration cycle 400. The refrigerant in the refrigeration cycle 400 is cooled more effectively because it is directly heat-exchanged with the outside air. The supercooling capacitor 330 is connected to the refrigeration cycle 400. Note that LT radiator 310 and HT radiator 320 are exemplary “first heat exchanger” and “second heat exchanger” of the present disclosure, respectively. The supercooling capacitor 330 is an example of a “third heat exchanger” of the present disclosure.

The refrigeration cycle 400 includes a chiller 410, an evaporator 420, a compressor 430, a water-cooled capacitor 440, an expansion valve 450, an expansion valve 460, a three-way valve 470, and a three-way valve 480.

The three-way valve 470 and the three-way valve 480 are connected by a flow path 475. The three-way valve 470 and the three-way valve 480 are configured to be able to switch whether the refrigerant from the water-cooled capacitor 440 flows to the supercooling capacitor 330 or to the supercooling capacitor 330 by flowing to the flow path 475.

The chiller 410 is connected to each of the refrigeration cycle 400 and the battery circuit 100. As a result, the refrigerant flowing through the refrigeration cycle 400 and the cooling liquid flowing through the battery circuit 100 are heat-exchanged in the chiller 410.

The refrigerant (vapor phase refrigerant or liquid phase refrigerant) circulating in the refrigeration cycle 400 flows through one/both of the first path of the compressor 430-water-cooled capacitor 440-supercooling capacitor 330 (or flow path 475)-expansion valve 460-evaporator 420-compressor 430 and the second path of the compressor 430-water-cooled capacitor 440-supercooling capacitor 330 (or flow path 475)-expansion valve 450-chiller 410-compressor 430.

The water-cooled capacitor 440 includes a condensing unit 441 and a liquid storage unit 442. The condensing unit 441 condenses the high-temperature and high-pressure gaseous refrigerant pumped from the compressor 430 to convert the gaseous refrigerant into a liquid refrigerant. In addition, the condensing unit 441 exchanges heat between the liquid refrigerant and the cooling liquid from the switching device 500. The liquid storage unit 442 performs gas-liquid separation of the liquid-phase refrigerant that has passed through the condensing unit 441. The supercooling capacitor 330 exchanges heat between the liquid-phase refrigerant that has passed through the liquid storage unit 442 and the outside air.

The switching device 500 is configured to be able to switch the circulation route of the heat medium (cooling liquid). The switching device 500 includes ports P1 to P16. The port P1 is an outlet port that allows coolant to flow toward LT radiator 310. The port P2 is an inlet port into which the coolant from LT radiator 310 flows. A flow path is not connected to each of the port P3 and P4. The port P5 is an outlet port that allows coolant to flow toward HT radiator 320. The port P6 is an inlet port into which the coolant from HT radiator 320 flows. The port P7 is an outlet port that allows coolant to flow toward the heater core 600. The port P8 is an inlet port into which the coolant from the heater core 600 flows.

The port P9 is the outlet port through which the coolant flows towards the water pump 220 (eAxle 210). The port P10 is an inlet port into which the coolant from eAxle 210 flows. The port P11 is an outlet port that allows coolant to flow toward the battery 110. The port P12 is an inlet port through which the coolant from the chiller 410 flowing through the battery circuit 100 flows. The port P13 is an inlet port into which the coolant from the water pump 700 provided between the condensing unit 441 and the switching device 500 flows. The port P14 is an outlet port through which the coolant flows toward the condensing unit 441. The ports P13 and P14 are connected to the condensing unit 441 by a flow path 710 and a flow path 720, respectively. The coolant flowing out of the condensing unit 441 flows into the switching device 500 through the flow path 710 from the port P13. The cooling liquid flowing out of the port P14 flows into the condensing unit 441 through the flow path 720, and the cooling liquid flowing into the condensing unit 441 is heat-exchanged with the refrigerant of the refrigeration cycle 400 in the condensing unit 441, and then flows out toward the water pump 700. A flow path is not connected to each of the port P15 and P16. Each of the flow path 710 and the flow path 720 is an example of the “first flow path” of the present disclosure. The flow path 710 and the flow path 720 are examples of the “first direction flow path” and the “second direction flow path” of the present disclosure, respectively.

ECU 80 controls the thermal management circuit 10. ECU 80 includes a processor 81, a memory 82, a storage 83, and an interface 84. ECU 80 controls the status of the switching device 500, the three-way valve 470, and the three-way valve 480, and adjusts the flow rate and the like of the water pumps.

Here, in the conventional thermal management circuit, it is desired to make the heat exchange efficiency of the heat medium (cooling liquid, refrigerant) more easily adjustable.

Therefore, in the thermal management circuit 10 of the first embodiment, the switching device 500 switches the connection state between each of LT radiator 310, HT radiator 320, and the supercooling capacitor 330 and each of the battery circuit 100, the low-temperature circuit 200, and the refrigeration cycle 400. Specifically, the thermal management circuit 10 may take the circuit pattern shown in FIG. 2 to FIG. 6 below.

FIG. 2 is a diagram illustrating a circuit pattern 1A of the thermal management circuit 10. In the embodiment illustrated in FIG. 2, eAxle 210 is connected to LT radiator 310 via the switching device 500. The condensing unit 441 is connected to HT radiator 320 via the switching device 500. In addition, since the port P11 and P12 (see FIG. 1) of the switching device 500 are closed, the coolant does not flow through the chiller 410. In addition, since the port P7 and P8 (see FIG. 1) of the switching device 500 are closed, the coolant does not flow through the heater core 600. Each of the three-way valve 470 and the three-way valve 480 is controlled so that the refrigerant in the refrigeration cycle 400 flows through the supercooling capacitor 330. In the circuit pattern 1A, HT radiator 320 and LT radiator 310 are separated from each other.

Further, as shown in FIG. 2, each of LT radiator 310 and the supercooling capacitor 330 is disposed upstream of HT radiator 320 in the flow direction of the outside air flowing into the heat exchange device 300. Specifically, the outside air flows into the interior of the vehicle from the grille 1b provided at the front end of electrified vehicle 1a. Therefore, each of LT radiator 310 and the supercooling capacitor 330 is disposed forward of HT radiator 320 in the front-rear direction of electrified vehicle 1a. Further, when viewed from the front of electrified vehicle 1a, each of LT radiator 310 and the supercooling capacitor 330 may be disposed at a position where at least a part does not overlap with HT radiator 320. As a result, the outside air warmed by passing through LT radiator 310 and the supercooling capacitor 330 can be suppressed from passing through HT radiator 320.

FIG. 3 is a diagram illustrating a circuit pattern 1B of the thermal management circuit 10. In the embodiment shown in FIG. 3, each of eAxle 210 and condensing unit 441 is connected to LT radiator 310 and HT radiator 320 via the switching device 500. The chiller 410 and the heater core 600 are the same as in FIG. 2. Each of the three-way valve 470 and the three-way valve 480 is controlled so that the refrigerant in the refrigeration cycle 400 flows through the supercooling capacitor 330. In the circuit pattern 1B, HT radiator 320 and LT radiator 310 are integrated.

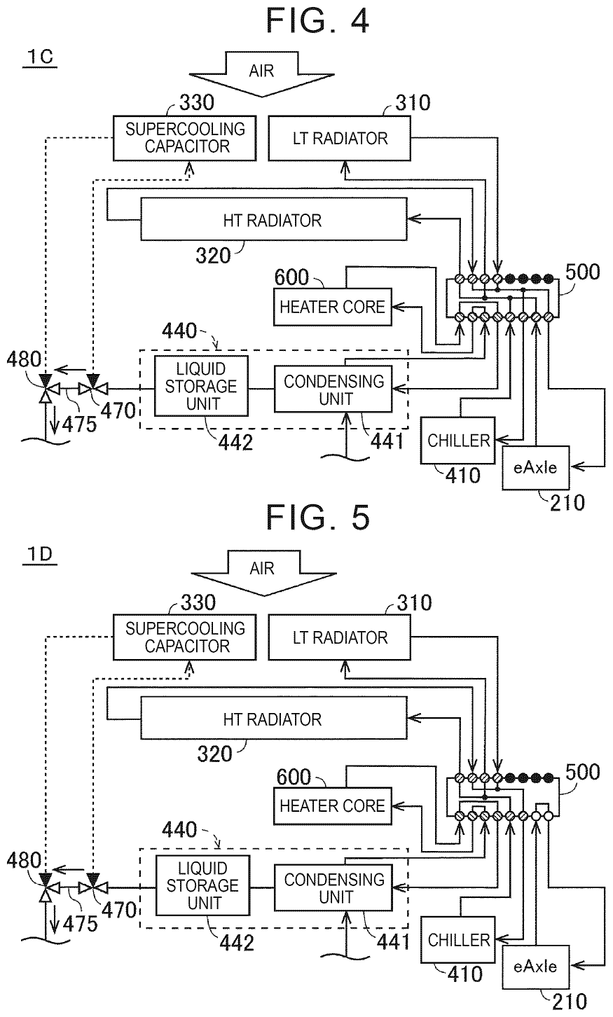

FIG. 4 is a diagram illustrating a circuit pattern 1C of the thermal management circuit 10. In the embodiment illustrated in FIG. 4, each of eAxle 210 and the chiller 410 is connected to LT radiator 310 and HT radiator 320 via the switching device 500. The condensing unit 441 is connected to the heater core 600 via the switching device 500. Each of the three-way valve 470 and the three-way valve 480 is controlled so that the refrigerant in the refrigeration cycle 400 flows through the flow path 475 without flowing through the supercooling capacitor 330. In the circuit pattern 1C, HT radiator 320 and LT radiator 310 are integrated.

FIG. 5 is a diagram illustrating a circuit pattern 1D of the thermal management circuit 10. In the embodiment illustrated in FIG. 5, the chiller 410 is connected to LT radiator 310 and HT radiator 320 via the switching device 500. The condensing unit 441 is connected to the heater core 600 via the switching device 500. In addition, the switching device 500 is controlled so that eAxle 210 (low-temperature circuit 200) is separated from other circuits and is independent. Each of the three-way valve 470 and the three-way valve 480 is controlled so that the refrigerant in the refrigeration cycle 400 flows through the flow path 475 without flowing through the supercooling capacitor 330. In the circuit pattern 1D, HT radiator 320 and LT radiator 310 are integrated.

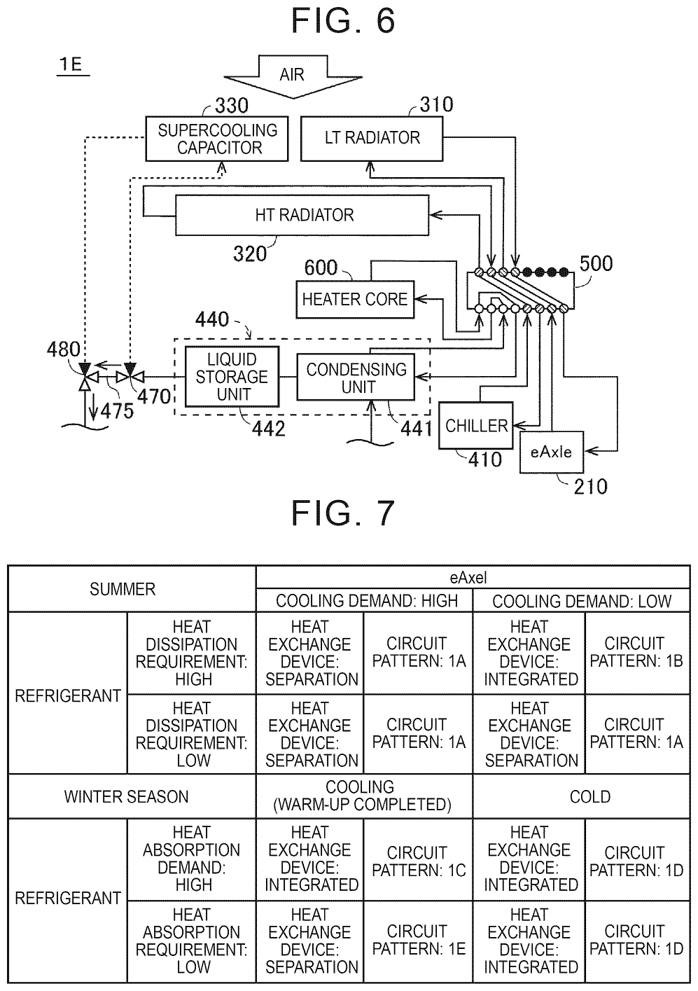

FIG. 6 is a diagram illustrating a circuit pattern 1E of the thermal management circuit 10. In the embodiment illustrated in FIG. 6, the chiller 410 is connected to HT radiator 320 via the switching device 500. eAxle 210 is connected to LT radiator 310 via the switching device 500. The condensing unit 441 is connected to the heater core 600 via the switching device 500. Each of the three-way valve 470 and the three-way valve 480 is controlled so that the refrigerant in the refrigeration cycle 400 flows through the flow path 475 without flowing through the supercooling capacitor 330. In the circuit pattern 1E, HT radiator 320 and LT radiator 310 are separated from each other.

FIG. 7 is a diagram illustrating a circuit pattern of the thermal management circuit 10 corresponding to each of the plurality of temperature conditions. For example, in summer, the circuit pattern is switched based on the cooling request of eAxle 210 and the heat dissipation request of the refrigerant (the cooling request of the battery 110). When the cooling demand of eAxle 210 is high and the heat radiation demand of the refrigerant is high, the thermal management circuit 10 is switched to the circuit pattern 1A (see FIG. 2). When the cooling demand of eAxle 210 is low and the heat radiation demand of the refrigerant is high, the thermal management circuit 10 is switched to the circuit pattern 1B (see FIG. 3). When the cooling demand of eAxle 210 is high and the heat radiation demand of the refrigerant is low, the thermal management circuit 10 is switched to the circuit pattern 1A. When the cooling demand of eAxle 210 is low and the heat radiation demand of the refrigerant is low, the thermal management circuit 10 is switched to the circuit pattern 1A. Note that the case where the cooling demand for eAxle 210 is high may be, for example, a case where the temperature of the cooling liquid flowing through the low-temperature circuit 200 is equal to or higher than a predetermined value, or a case where the temperature of e Axle 210 is equal to or higher than a predetermined value. The case where the heat radiation request of the refrigerant is high may be, for example, a case where the temperature of the cooling liquid flowing through the battery circuit 100 is equal to or higher than a predetermined value, or a case where the temperature of the battery 110 is equal to or higher than a predetermined value.

Further, in winter, the circuit pattern is switched based on the cooling request of eAxle 210 and the heat absorption request of the refrigerant. For example, when the cooling of eAxle 210 is required (for example, warm-up of eAxle 210 is completed) and the heat absorption demand of the refrigerant is higher, the thermal management circuit 10 is switched to the circuit pattern 1C (see FIG. 4). When the cooling time of eAxle 210 (i.e., there is no cooling request) and the heat absorption request of the refrigerant is higher, the thermal management circuit 10 is switched to the circuit pattern 1D (see FIG. 5). When cooling of eAxle 210 is required and the heat absorption demand of the refrigerant is low, the thermal management circuit 10 is switched to the circuit pattern 1E (see FIG. 6). When eAxle 210 is cold and the heat absorption demand of the coolant is low, the thermal management circuit 10 is switched to the circuit pattern 1D. Note that the case where there is a demand for cooling eAxle 210 may be, for example, a case where warm-up of eAxle 210 is completed as described above, or a case where the temperature of eAxle 210 (the cooling liquid of the low-temperature circuit 200) is equal to or higher than a predetermined value. In addition, the case where the heat absorption request of the refrigerant is high may be a case where an output of heat pump heating equal to or higher than a predetermined value is required.

As described above, in the first embodiment, the switching device 500 switches the connection state between LT radiator 310, HT radiator 320, and the supercooling capacitor 330 and the battery circuit 100, the low-temperature circuit 200, and the refrigeration cycle 400. As a result, the heat of the heat medium (coolant, refrigerant) using LT radiator 310, HT radiator 320, and the supercooling capacitor 330 can be exchanged in accordance with the temperature required by each of the battery circuit 100, the low-temperature circuit 200, and the refrigeration cycle 400. As a result, the heat exchange amount (efficiency) of the heat medium can be easily adjusted. Consequently, the cooling performance of the battery 110, eAxel 210, and the like can be improved, and the running performance of electrified vehicle 1a and the charging performance of the battery 110 can be improved. In addition, the heat absorption performance (heat pump heating performance) can be improved, and the cruising range of electrified vehicle 1a can be increased.

Each of LT radiator 310 and the supercooling capacitor 330 is disposed upstream of HT radiator 320 in the flow direction of the outside air flowing into the heat exchange device 300. Here, a relatively low upper limit temperature (e.g., 65° C.) is set for the coolant of the low-temperature circuit 200 that is heat-exchanged with eAxle 210. Therefore, since LT radiator 310 that mainly cools eAxle 210 is disposed upstream in the flow direction of the outside air, it is possible to suppress the outside air at a temperature equal to or higher than the lower limit temperature value from flowing to LT radiator 310. As a result, the temperature of the outside air flowing through LT radiator 310 becomes relatively low, so that the air-water temperature differential in LT radiator 310 can be made larger. Therefore, since the same cooling performance can be realized with a smaller heat-exchange area, the size of LT radiator 310 can be reduced. Consequently, the supercooling capacitor 330 can be disposed in the space formed by the miniaturization of LT radiator 310.

### Second Embodiment

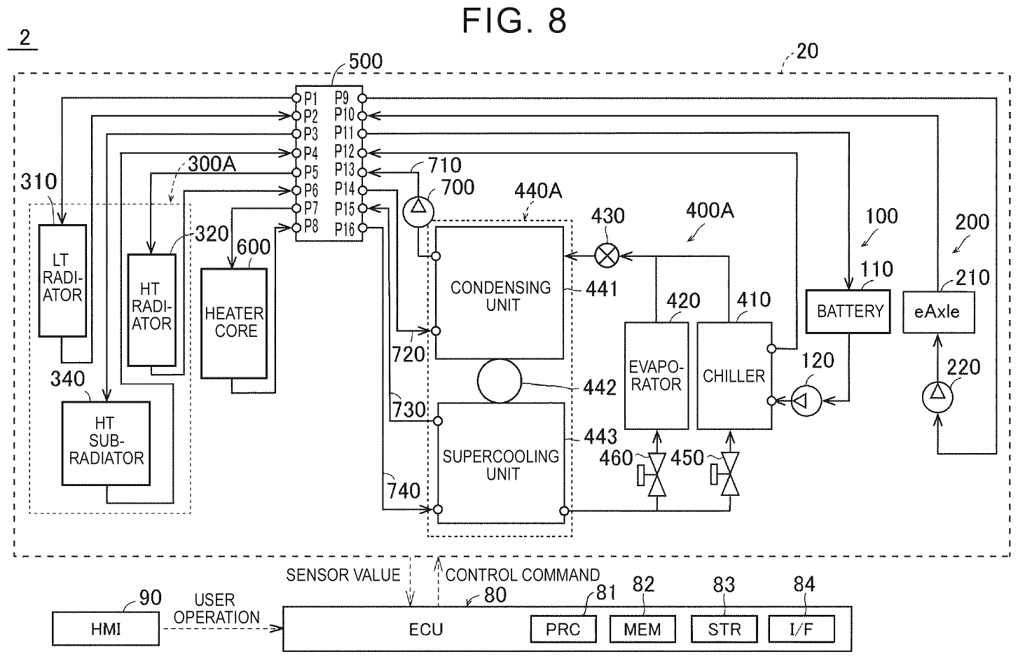

Next, referring to FIG. 8 to FIG. 14, second embodiment of the present disclosure will be described. In the second embodiment, the water-cooled capacitor 440A is provided with the supercooling unit 443. The same components as those of the first embodiment are denoted by the same reference numerals as those of the first embodiment, and the repetitive description thereof will not be given.

FIG. 8 is a diagram illustrating an overall configuration of the thermal management system 2 including the thermal management circuit 20 according to the second embodiment. The thermal management circuit 20 differs from the thermal management circuit 10 of the first embodiment in that a refrigeration cycle 400A is provided in place of the refrigeration cycle 400 and a heat exchange device 300A is provided in place of the heat exchange device 300.

The refrigeration cycle 400A differs from the refrigeration cycle 400 of the first embodiment in that a water-cooled capacitor 440A is included instead of the water-cooled capacitor 440. The water-cooled capacitor 440A includes a condensing unit 441, a liquid storage unit 442, and a supercooling unit 443. The condensing unit 441, the liquid storage unit 442, and the supercooling unit 443 are connected in series with each other in the refrigeration cycle 400A (in a circulation route of the refrigerant flowing through the refrigeration cycle 400A). The refrigerant in the refrigeration cycle 400A flows in the order of the condensing unit 441, the liquid storage unit 442, and the supercooling unit 443. The supercooling unit 443 cools the refrigerant changed to the liquid phase in the condensing unit 441 by heat exchange with the cooling liquid flowing through the supercooling unit 443. The refrigerant flowing to the supercooling unit 443 flows toward the expansion valves 450 and 460.

The heat exchange device 300A differs from the heat exchange device 300 of the first embodiment in that it includes a HT sub-radiator 340 instead of the supercooling capacitor 330. The arrangement position of HT sub-radiator 340 is the same as the arrangement position of the supercooling capacitor 330. The thermal management circuit 30 has excellent heat absorption performance by providing three radiators. HT sub-radiator 340 is an exemplary “third heat exchanger” of the present disclosure.

The port P15 of the switching device 500 is an inlet port into which the cooling liquid from the supercooling unit 443 flows. The port P15 and the supercooling unit 443 are connected by a flow path 730. The port P16 of the switching device 500 is an outlet port through which the coolant flows toward the supercooling unit 443. The port P16 and the supercooling unit 443 are connected by a flow path 740. Each of the flow path 730 and the flow path 740 is an example of a “second flow path” of the present disclosure. The flow path 730 and the flow path 740 are examples of the “first direction flow path” and the “second direction flow path” of the present disclosure, respectively.

The port P3 of the switching device 500 is an outlet port through which the coolant flows toward HT sub-radiator 340. The port P4 of the switching device 500 is an inlet port into which the coolant from HT sub-radiator 340 flows.

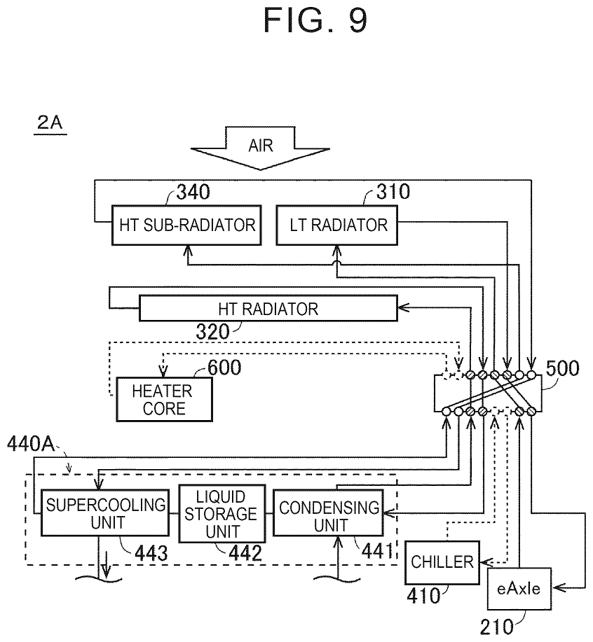

FIG. 9 is a diagram illustrating a circuit pattern 2A of the thermal management circuit 20. In the embodiment illustrated in FIG. 9, eAxle 210 is connected to LT radiator 310 via the switching device 500. The condensing unit 441 is connected to HT radiator 320 via the switching device 500. The supercooling unit 443 is connected to HT sub-radiator 340 via the switching device 500. When the port P11 and P12 (see FIG. 8) of the switching device 500 are closed, the coolant does not flow through the chiller 410. When P7 and P8 (see FIG. 8) of the switching device 500 are closed, the coolant does not flow through the heater core 600. In the circuit pattern 2A, HT radiator 320, LT radiator 310, and HT sub-radiator 340 are separated from each other.

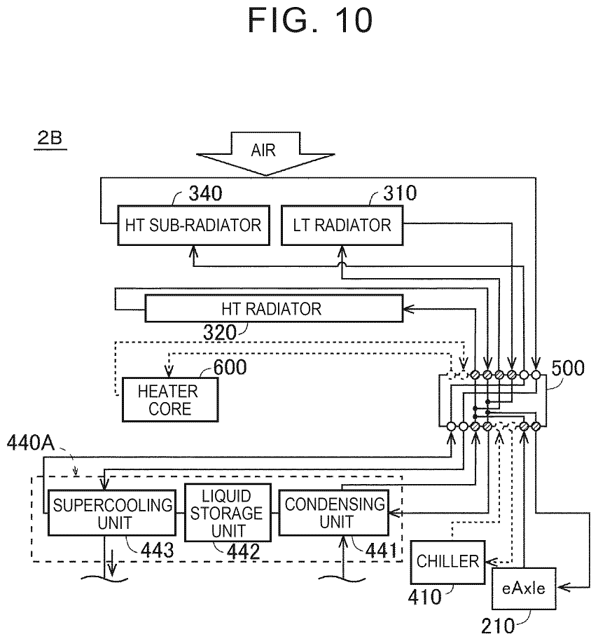

FIG. 10 is a diagram illustrating a circuit pattern 2B of the thermal management circuit 20. In the embodiment shown in FIG. 10, each of eAxle 210 and condensing unit 441 is connected to LT radiator 310 and HT radiator 320 via the switching device 500. The supercooling unit 443 is connected to HT sub-radiator 340 via the switching device 500. The chiller 410 and the heater core 600 are the same as in FIG. 9. In the circuit pattern 2B, HT radiator 320 and LT radiator 310 are integrated.

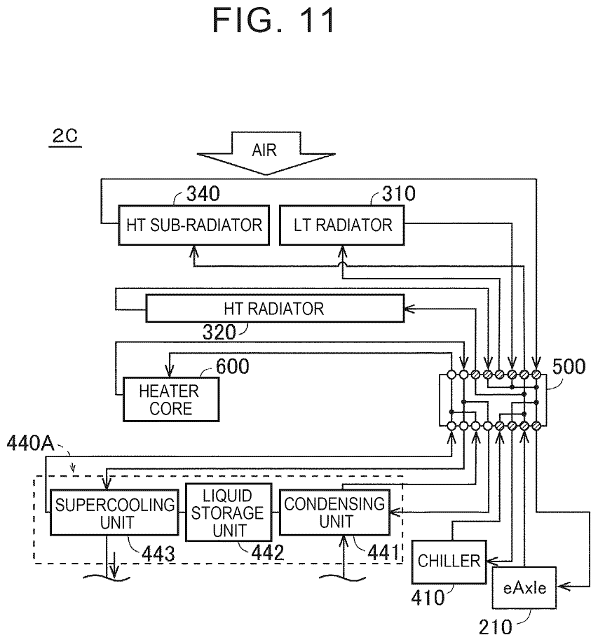

FIG. 11 is a diagram illustrating a circuit pattern 2C of the thermal management circuit 20. In the embodiment illustrated in FIG. 11, each of eAxle 210 and the chiller 410 is connected to LT radiator 310, HT radiator 320, and HT sub-radiator 340 via the switching device 500. Each of the condensing unit 441 and the supercooling unit 443 is connected to the heater core 600 via the switching device 500. In the circuit pattern 2C, HT radiator 320, LT radiator 310, and HT sub-radiator 340 are integrated.

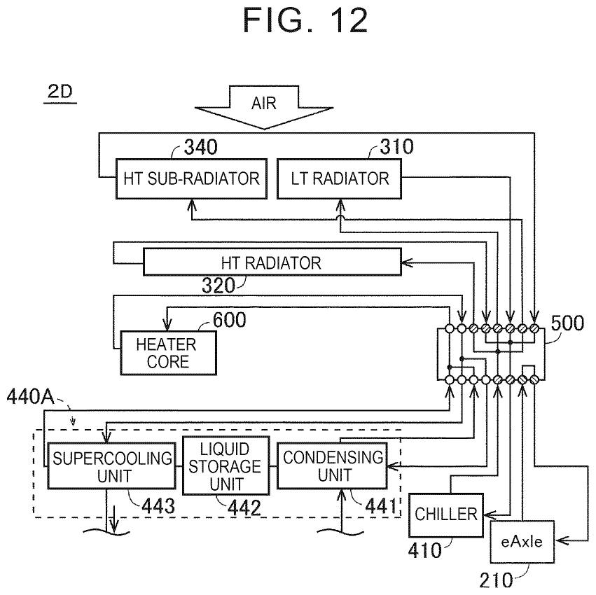

FIG. 12 is a diagram illustrating a circuit pattern 2D of the thermal management circuit 20. In the embodiment illustrated in FIG. 12, the chiller 410 is connected to LT radiator 310, HT radiator 320, and HT sub-radiator 340 via the switching device 500. Each of the condensing unit 441 and the supercooling unit 443 is connected to the heater core 600 via the switching device 500. The switching device 500 is controlled so that eAxle 210 (low-temperature circuit 200) is separated from other circuits and is independent. In the circuit pattern 2D, HT radiator 320, LT radiator 310, and HT sub-radiator 340 are integrated.

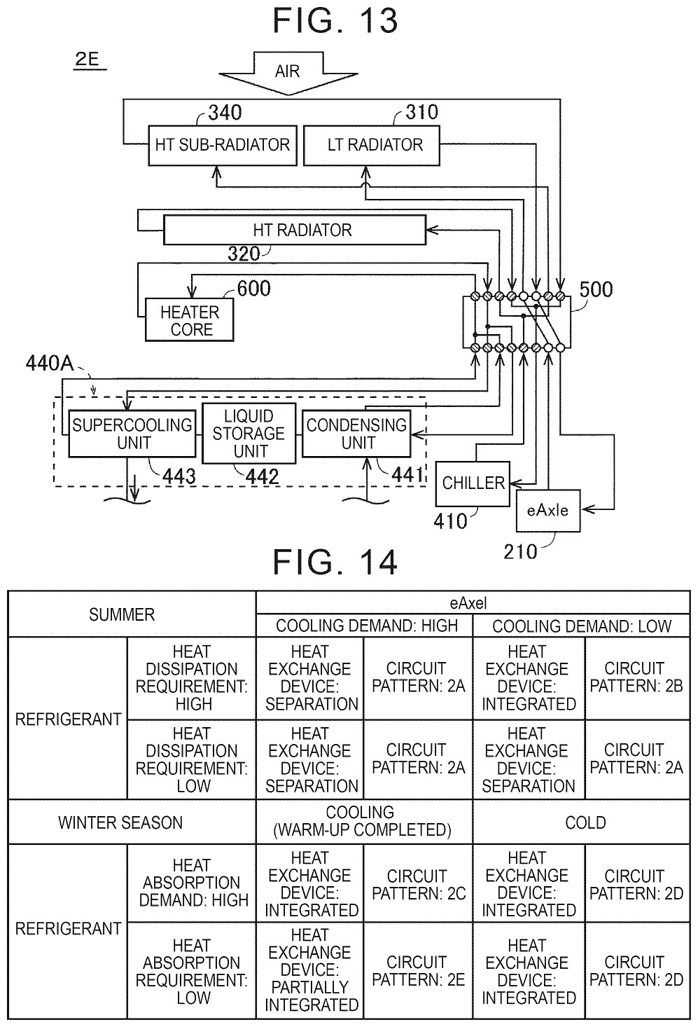

FIG. 13 is a diagram illustrating a circuit pattern 2E of the thermal management circuit 20. In the embodiment illustrated in FIG. 13, the chiller 410 is connected to HT radiator 320 and HT sub-radiator 340 via the switching device 500. eAxle 210 is connected to LT radiator 310 via the switching device 500. Each of the condensing unit 441 and the supercooling unit 443 is connected to the heater core 600 via the switching device 500. In the circuit pattern 2E, HT radiator 320 and HT sub-radiator 340 are integrated.

FIG. 14 is a diagram illustrating a circuit pattern of the thermal management circuit 20 corresponding to each of the plurality of temperature conditions. For example, in summer, when the cooling demand of eAxle 210 is high and the heat radiation demand of the refrigerant is high, the thermal management circuit 20 is switched to the circuit pattern 2A (see FIG. 9). When the cooling demand of eAxle 210 is low and the heat radiation demand of the refrigerant is high, the thermal management circuit 20 is switched to the circuit pattern 2B (see FIG. 10). When the cooling demand of eAxle 210 is high and the heat radiation demand of the refrigerant is low, the thermal management circuit 20 is switched to the circuit pattern 2A. When the cooling demand of eAxle 210 is low and the heat radiation demand of the refrigerant is low, the thermal management circuit 20 is switched to the circuit pattern 2A.

Further, in winter, when cooling of eAxle 210 is required and the heat absorption demand of the refrigerant is higher, the thermal management circuit 20 is switched to the circuit pattern 2C (see FIG. 11). When eAxle 210 is cold and the heat absorption demand of the coolant is high, the thermal management circuit 20 is switched to the circuit pattern 2D (see FIG. 12). When cooling of eAxle 210 is required and the heat absorption demand of the refrigerant is low, the thermal management circuit 20 is switched to the circuit pattern 2E (see FIG. 13). When eAxle 210 is cold and the heat absorption demand of the coolant is low, the thermal management circuit 20 is switched to the circuit pattern 2D.

Note that other configurations and effects are the same as those of the first embodiment, and therefore, repetitive description will not be given.

### Third Embodiment

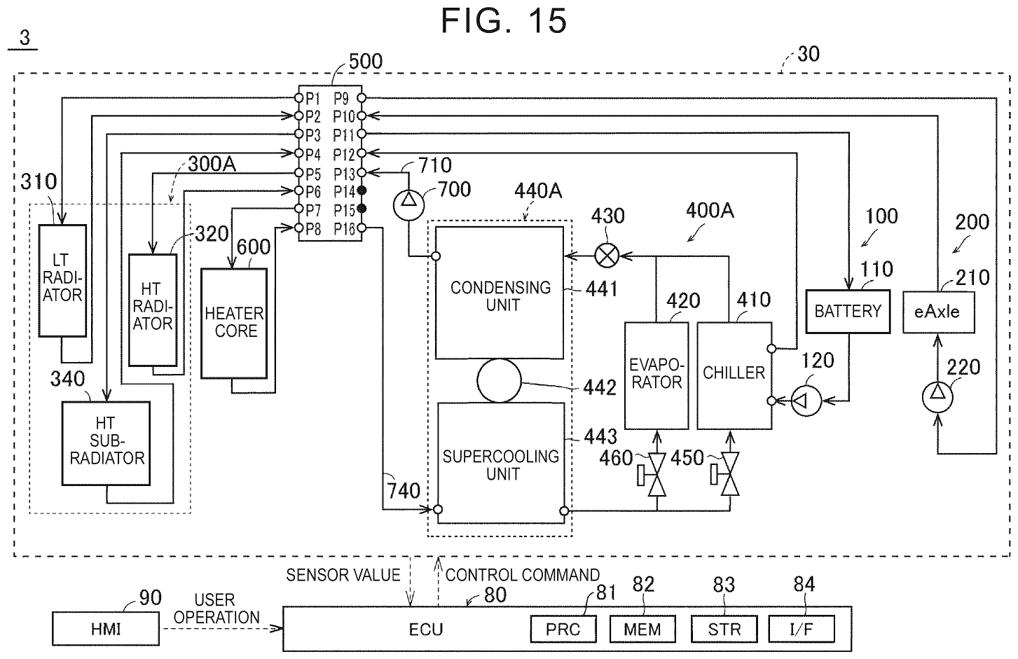

Referring to FIG. 15 to FIG. 21, a third embodiment of the present disclosure will be described. The third embodiment differs from the second embodiment in the configuration of the flow path between the water-cooled capacitor 440A and the switching device 500. The same components as those of the second embodiment are denoted by the same reference numerals as those of the second embodiment, and the repetitive description thereof will not be given.

FIG. 15 is a diagram illustrating an overall configuration of the thermal management system 3 including the thermal management circuit 30 according to the third embodiment. The thermal management circuit 30 is different from the thermal management circuit 20 of the second embodiment in that the flow path 720 and the flow path 730 (both of which are shown in FIG. 8) are not provided. That is, in the third embodiment, the condensing unit 441 and the switching device 500 are connected only by the flow path 710. In other words, the flow path connecting the condensing unit 441 and the switching device 500 is constituted by only the flow path 710. The supercooling unit 443 and the switching device 500 are connected by only the flow path 740. In other words, the flow path connecting the supercooling unit 443 and the switching device 500 is constituted by only the flow path 740. In this case, the flow path 710 is an example of the “third flow path” and the “third direction flow path” of the present disclosure. The flow path 740 is an example of the “fourth flow path” and the “fourth direction flow path” of the present disclosure.

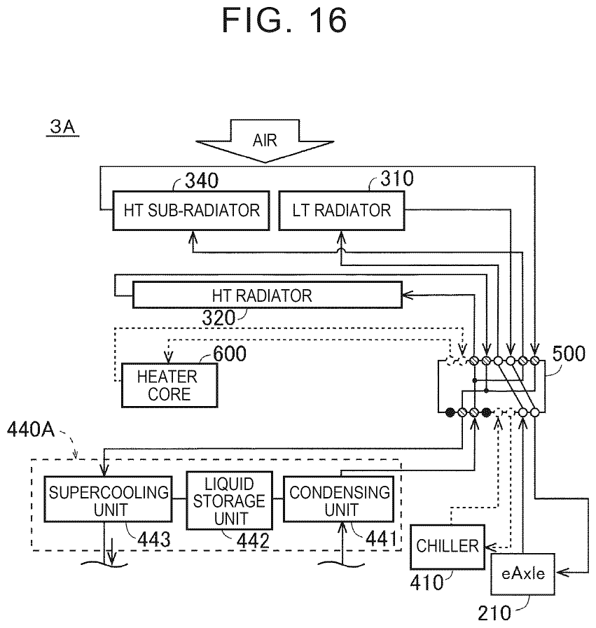

FIG. 16 is a diagram illustrating a circuit pattern 3A of the thermal management circuit 30. In the embodiment illustrated in FIG. 16, eAxle 210 is connected to LT radiator 310 via the switching device 500. The water-cooled capacitor 440A is connected to HT radiator 320 and HT sub-radiator 340 via the switching device 500. In addition, since the port P11 and P12 (see FIG. 15) of the switching device 500 are closed, the coolant does not flow through the chiller 410. In addition, since the port P7 and P8 (see FIG. 15) of the switching device 500 are closed, the coolant does not flow through the heater core 600. In the circuit pattern 3A, HT radiator 320 and HT sub-radiator 340 are integrated.

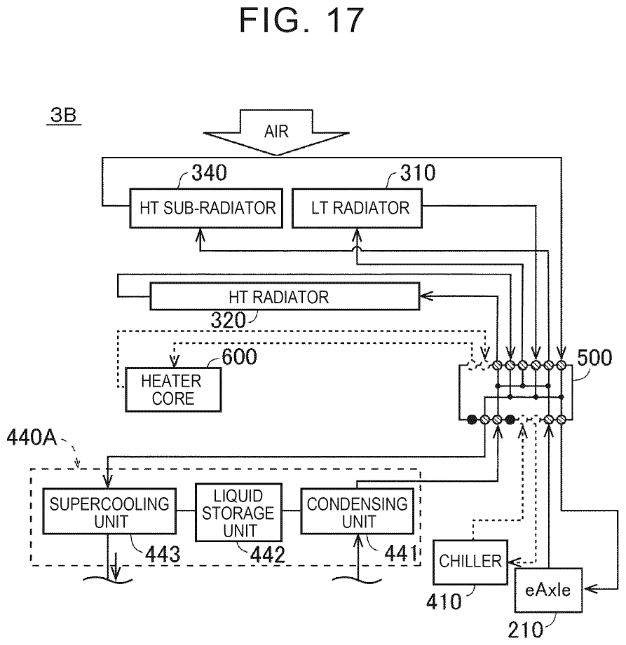

FIG. 17 is a diagram illustrating a circuit pattern 3B of the thermal management circuit 30. In the embodiment illustrated in FIG. 17, each of eAxle 210 and the water-cooled capacitor 440A is connected to LT radiator 310, HT radiator 320, and HT sub-radiator 340 via the switching device 500. The chiller 410 and the heater core 600 are the same as in FIG. 16. In the circuit pattern 3B, HT radiator 320, LT radiator 310, and HT sub-radiator 340 are integrated.

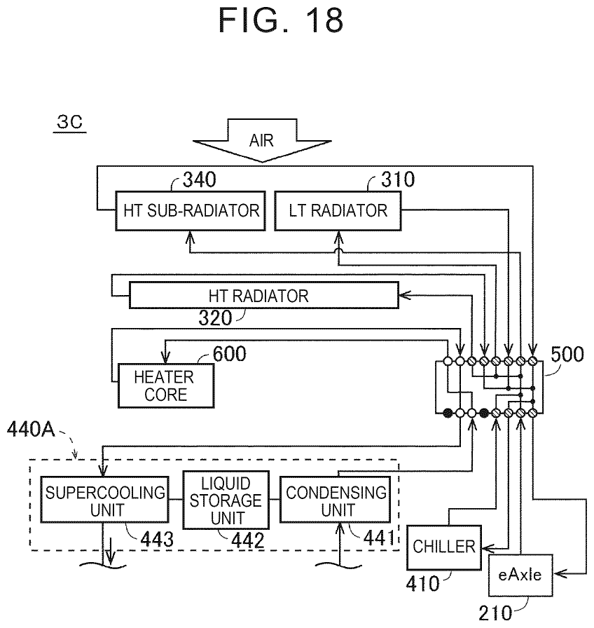

FIG. 18 is a diagram illustrating a circuit pattern 3C of the thermal management circuit 30. In the embodiment illustrated in FIG. 18, each of eAxle 210 and the chiller 410 is connected to LT radiator 310, HT radiator 320, and HT sub-radiator 340 via the switching device 500. The water-cooled capacitor 440A is connected to the heater core 600 via a switching device 500. In the circuit pattern 3C, HT radiator 320, LT radiator 310, and HT sub-radiator 340 are integrated.

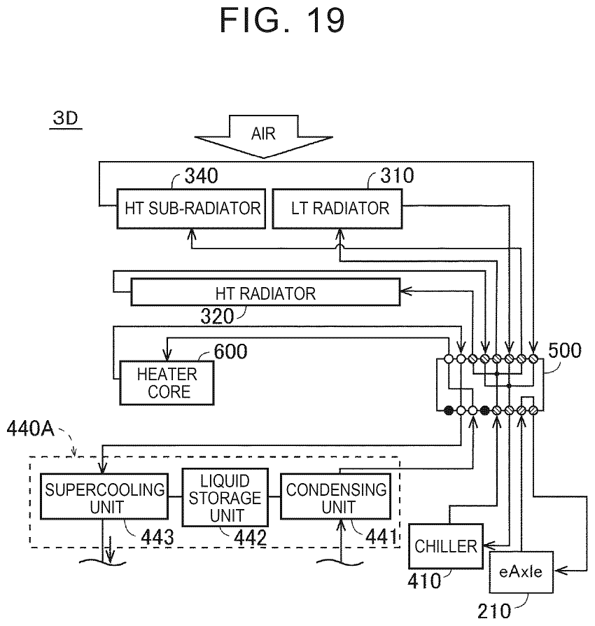

FIG. 19 is a diagram illustrating a circuit pattern 3D of the thermal management circuit 30. In the embodiment illustrated in FIG. 19, the chiller 410 is connected to LT radiator 310, HT radiator 320, and HT sub-radiator 340 via the switching device 500. The water-cooled capacitor 440A is connected to the heater core 600 via a switching device 500. The switching device 500 is controlled so that eAxle 210 (low-temperature circuit 200) is separated from other circuits and is independent. In the circuit pattern 3D, HT radiator 320, LT radiator 310, and HT sub-radiator 340 are integrated.

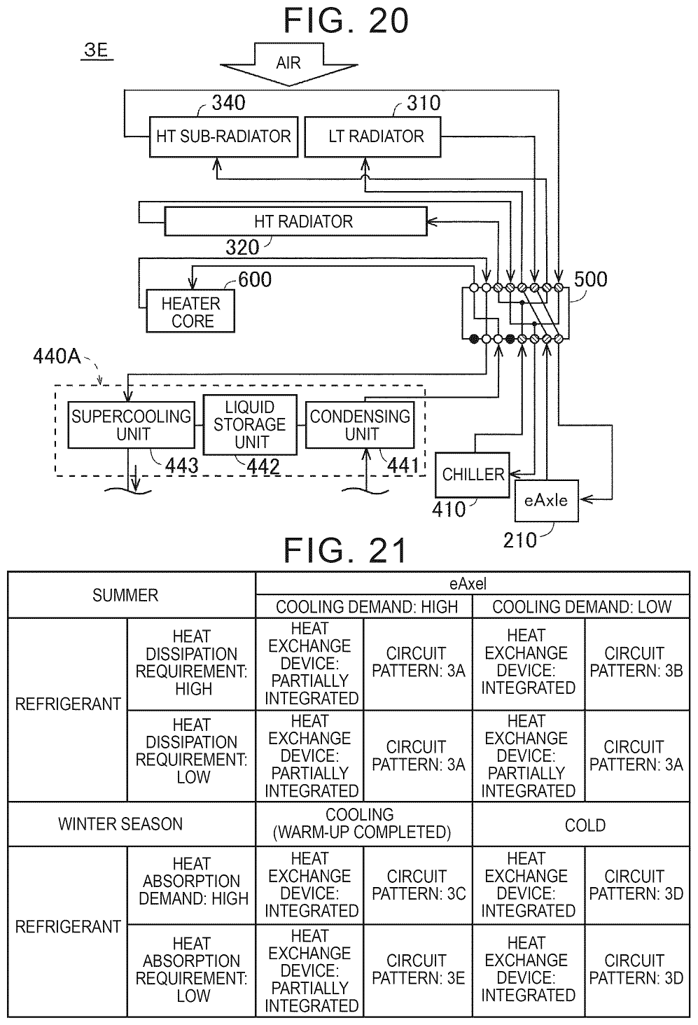

FIG. 20 is a diagram illustrating a circuit pattern 3E of the thermal management circuit 30. In the embodiment illustrated in FIG. 20, the chiller 410 is connected to HT radiator 320 and HT sub-radiator 340 via the switching device 500. The eAxle 210 is connected to LT radiator 310 via the switching device 500. The water-cooled capacitor 440A is connected to the heater core 600 via a switching device 500. In the circuit pattern 2E, HT radiator 320 and HT sub-radiator 340 are integrated.

FIG. 21 is a diagram illustrating a circuit pattern of the thermal management circuit 30 corresponding to each of the plurality of temperature conditions. For example, in summer, when the cooling demand of eAxle 210 is high and the heat radiation demand of the refrigerant is high, the thermal management circuit 30 is switched to the circuit pattern 3A (see FIG. 16). When the cooling demand of eAxle 210 is low and the heat radiation demand of the refrigerant is high, the thermal management circuit 30 is switched to the circuit pattern 3B (see FIG. 17). When the cooling demand of eAxle 210 is high and the heat radiation demand of the refrigerant is low, the thermal management circuit 30 is switched to the circuit pattern 3A. When the cooling demand of eAxle 210 is low and the heat radiation demand of the refrigerant is low, the thermal management circuit 30 is switched to the circuit pattern 3A.

Further, in winter, when cooling of eAxle 210 is required and the heat absorption demand of the refrigerant is higher, the thermal management circuit 30 is switched to the circuit pattern 3C (see FIG. 18). When eAxle 210 is cold and the heat absorption demand of the coolant is high, the thermal management circuit 30 is switched to the circuit pattern 3D (see FIG. 19). When cooling of eAxle 210 is required and the heat absorption demand of the refrigerant is low, the thermal management circuit 30 is switched to the circuit pattern 3E (see FIG. 20). When eAxle 210 is cold and the heat absorption demand of the coolant is low, the thermal management circuit 30 is switched to the circuit pattern 3D.

Note that other configurations and effects are the same as those of the first and second embodiments, and therefore, repetitive description will not be given.

In the first to third embodiments, the thermal management circuit is mounted on electrified vehicle. thermal management circuit may be mounted on an electrical apparatus other than electrified vehicle (e.g., a stationary power storage device).

In the above embodiment, HT radiator 320 and the supercooling capacitor 330 (HT sub-radiator 340) are provided in front of (upstream of the wind) LT radiator 310 in the front-rear direction of electrified vehicle 1a. However, the present disclosure is not limited thereto. The positional relation between HT radiator 320 and the supercooling capacitor 330 (HT sub-radiator 340) and LT radiator 310 is not limited to the above-described exemplary embodiment. For example, HT radiator 320 and the supercooling capacitor 330 (HT sub-radiator 340) and LT radiator 310 may be arranged side by side in the left-right direction (a direction intersecting the flow direction of the wind).

The embodiment disclosed herein shall be construed as exemplary and not restrictive in all respects. The scope of the present disclosure is shown by the claims rather than by the above description of the embodiments, and is intended to include all modifications within the meaning and scope equivalent to those of the claims.

What is claimed is:

1. A thermal management circuit installed in an electrical apparatus, the thermal management circuit comprising:
an apparatus arrangement circuit through which a heat medium that exchanges heat with a temperature adjustment target apparatus is circulated, the temperature adjustment target apparatus being an apparatus that is a target of temperature adjustment;
a refrigeration cycle that is connected to a chiller and a water-cooled capacitor;
a heat exchange device that performs heat exchange between outside air and the heat medium; and
a switching device that is able to switch a circulation route of the heat medium, wherein:
the heat exchange device includes a first heat exchanger, a second heat exchanger, and a third heat exchanger that are provided separately from each other; and
a connection state between each of the first heat exchanger, the second heat exchanger, and the third heat exchanger and each of the apparatus arrangement circuit and the refrigeration cycle is switched by the switching device.

2. The thermal management circuit according to claim 1, wherein:
the third heat exchanger is connected to the refrigeration cycle;
the water-cooled capacitor includes a condensing unit that changes the heat medium from a vapor phase to a liquid phase; and
in the third heat exchanger, the heat medium changed to the liquid phase in the condensing unit and the outside air exchange heat.

3. The thermal management circuit according to claim 1, wherein:
the water-cooled capacitor includes a condensing unit that changes the heat medium from a vapor phase to a liquid phase, and a supercooling unit that cools the heat medium changed to the liquid phase in the condensing unit;
the condensing unit and the supercooling unit are connected to the switching device through a first flow path and a second flow path, respectively; and
each of the first flow path and the second flow path includes a first direction flow path through which the heat medium circulates toward the switching device, and a second direction flow path through which the heat medium circulates in a direction opposite to a direction in which the heat medium circulates in the first direction flow path.

4. The thermal management circuit according to claim 1, wherein:
the water-cooled capacitor includes a condensing unit that changes the heat medium from a vapor phase to a liquid phase, and a supercooling unit that cools the heat medium changed to the liquid phase in the condensing unit;
the condensing unit and the supercooling unit are connected to the switching device through a third flow path and a fourth flow path, respectively;
the third flow path is constituted by a third direction flow path through which the heat medium circulates from the condensing unit toward the switching device; and
the fourth flow path is constituted by a fourth direction flow path through which the heat medium circulates from the switching device toward the supercooling unit.

5. The thermal management circuit according to claim 1, wherein each of the first heat exchanger and the third heat exchanger is disposed on an upstream side of the second heat exchanger in a circulation direction of the outside air flowing into the heat exchange device.
